(19) United States
(12) Patent Application Publication
(10) Pub. No.: US 2025/0158592 A1
(43) Pub. Date: May 15, 2025

(54) ACOUSTIC WAVE DEVICE

(71) Applicant: Murata Manufacturing Co., Ltd., Nagaokakyo-shi (JP)

(72) Inventors: Sho NAGATOMO, Nagaokakyo-shi (JP); Naohiro NODAKE, Nagaokakyo-shi (JP); Masakazu MIMURA, Nagaokakyo-shi (JP)

(21) Appl. No.: 19/019,954

(22) Filed: Jan. 14, 2025

Related U.S. Application Data
(63) Continuation of application No. PCT/JP2023/029304, filed on Aug. 10, 2023.
(60) Provisional application No. 63/397,825, filed on Aug. 13, 2022.

(51) Int. Cl. H03H 9/13; H03H 9/02; H03H 9/17

(52) U.S. Cl. CPC H03H 9/132; H03H 9/02031; H03H 9/02157; H03H 9/02228; H03H 9/173; H03H 9/175; H03H 9/176

(57) ABSTRACT

An acoustic wave device includes a piezoelectric layer, first and second comb-shaped electrodes respectively including first and second busbars and first and second electrode fingers connected to the first and second busbars, and connected to input and output potentials, and a reference potential electrode including third electrode fingers aligned with the first and second electrode fingers in a direction in which the first and second electrode fingers are arranged, and connection electrodes connecting adjacent third electrode fingers, the reference potential electrode being at least partially provided between the first and second comb-shaped electrodes and connected to a reference potential. Starting from the first electrode finger, the first electrode finger, the third electrode finger, the second electrode finger, and the third electrode finger define one period. The reference potential electrode includes at least three potential connection portions connected to the reference potential.

### CROSS REFERENCE TO RELATED APPLICATIONS

This application the benefit of priority to Provisional Application No. 63/397,825 filed on Aug. 13, 2022 and is a Continuation application of PCT Application No. PCT/JP2023/029304 filed on Aug. 10, 2023. The entire contents of each application are hereby incorporated herein by reference.

### BACKGROUND OF THE INVENTION

### 1. Field of the Invention

The present invention relates to acoustic wave devices.

### 2. Description of the Related Art

Acoustic wave devices have heretofore been widely used in filters for mobile phones and the like. An acoustic wave device using bulk waves in a thickness-shear mode has recently been proposed, as described in U.S. Pat. No. 10,491,192. In this acoustic wave device, a piezoelectric layer is provided on a support. A pair of electrodes are provided on the piezoelectric layer. The pair of electrodes face each other on the piezoelectric layer and are connected to different potentials. An AC voltage is applied between the electrodes to excite bulk waves in the thickness-shear mode.

An acoustic wave device is, for example, an acoustic wave resonator, and is used in a ladder filter, for example. In order to obtain good characteristics in the ladder filter, the electrostatic capacitance ratio needs to be increased between a plurality of acoustic wave resonators. In this case, the electrostatic capacitances of some of the acoustic wave resonators in the ladder filter need to be increased.

In order to increase the electrostatic capacitance of the acoustic wave resonator, the acoustic wave resonator needs to be increased in size. For this reason, in the case of using such an acoustic wave resonator in a ladder filter, the ladder filter tends to be increased in size. In particular, a ladder filter having an acoustic wave resonator that uses a thickness-shear mode bulk wave with a small electrostatic capacitance tends to be increased in size.

The inventors of example embodiments of the present invention have discovered that when an acoustic wave device is used in a filter device, providing the following configuration of the acoustic wave device can obtain a suitable filter waveform without increasing the size. In this configuration, an electrode connected to a reference potential is disposed between an electrode connected to an input potential and an electrode connected to an output potential.

However, the inventors of example embodiments of the present invention have also discovered that, in the above configuration, the electrical resistance of the electrode connected to the reference potential easily becomes high. Therefore, when the acoustic wave device is used in a filter device, the electrical resistance of the acoustic wave device easily becomes high.

### SUMMARY OF THE INVENTION

Example embodiments of the present invention provide acoustic wave devices achieving miniaturization of a filter device and reducing electrical resistance.

An acoustic wave device according to an example embodiment of the present invention includes a piezoelectric layer, a first comb-shaped electrode on the piezoelectric layer, including a first busbar and a plurality of first electrode fingers each including one end connected to the first busbar, and being connected to an input potential, a second comb-shaped electrode on the piezoelectric layer, including a second busbar and a plurality of second electrode fingers each including one end connected to the second busbar and being interdigitated with the plurality of first electrode fingers, and being connected to an output potential, and a reference potential electrode including a plurality of third electrode fingers on the piezoelectric layer and aligned with the first electrode fingers and the second electrode fingers in a direction in which the first electrode fingers and the second electrode fingers are arranged, and a plurality of connection electrodes connecting adjacent third electrode fingers, in which the reference potential electrode is at least partially provided between the first comb-shaped electrode and the second comb-shaped electrode and connected to a reference potential, an order in which the first electrode finger, the second electrode finger, and the third electrode finger are arranged is such that, starting from the first electrode finger, the first electrode finger, the third electrode finger, the second electrode finger, and the third electrode finger define one period, and the reference potential electrode includes at least three potential connection portions connected to the reference potential.

Example embodiments of the present invention provide acoustic wave devices achieving miniaturization of a filter device and reducing electrical resistance.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view of an acoustic wave device according to a first example embodiment of the present invention.

FIG. 2 is a schematic plan view of the acoustic wave device according to the first example embodiment of the present invention.

FIG. 3 is a schematic elevational cross-sectional view illustrating the vicinity of first to third electrode fingers in the first example embodiment of the present invention.

FIG. 4 is a graph illustrating bandpass characteristics and reflection characteristics of the acoustic wave device according to the first example embodiment of the present invention.

FIG. 5 is a schematic plan view of an acoustic wave device of a reference example.

FIG. 6 is a diagram illustrating a map of a fractional band width with respect to Euler angles (0°, θ, ψ) of LiNbO₃ when d/p is infinitely close to 0.

FIG. 7 is a schematic plan view of an acoustic wave device according to a second example embodiment of the present invention.

FIG. 8 is a schematic plan view of an acoustic wave device according to a third example embodiment of the present invention.

FIG. 9 is a schematic plan view of an acoustic wave device according to a fourth example embodiment of the present invention.

FIG. 10A is a schematic perspective view illustrating an appearance of an acoustic wave device that uses a thickness-shear mode bulk wave, and FIG. 10B is a plan view illustrating an electrode structure on a piezoelectric layer.

FIG. 11 is a cross-sectional view of a portion taken along line A-A in FIG. 10A.

FIG. 12A is a schematic elevational cross-sectional view for explaining a Lamb wave propagating through a piezoelectric film of the acoustic wave device, and FIG. 12B is a schematic elevational cross-sectional view for explaining a thickness-shear mode bulk wave propagating through the piezoelectric film of the acoustic wave device.

FIG. 13 is a diagram illustrating an amplitude direction of the thickness-shear mode bulk wave.

FIG. 14 is a graph illustrating resonance characteristics of the acoustic wave device using the thickness-shear mode bulk wave.

FIG. 15 is a graph illustrating a relationship between d/p and a fractional band width of a resonator, where p is the center-to-center distance between adjacent electrodes and d is the thickness of the piezoelectric layer.

FIG. 16 is a plan view of the acoustic wave device using the thickness-shear mode bulk wave.

FIG. 17 is a diagram illustrating resonance characteristics of the acoustic wave device in a reference example where a spurious response appears.

FIG. 18 is a diagram illustrating a relationship between a fractional band width and a phase rotation amount of a spurious impedance normalized by about 180 degrees as a magnitude of spurious.

FIG. 19 is a diagram illustrating a relationship between d/2p and a metallization ratio MR.

FIG. 20 is a diagram illustrating a map of the fractional band width with respect to Euler angles (0°, θ, ψ) of LiNbO₃ when d/p is infinitely close to 0.

FIG. 21 is an elevational cross-sectional view of an acoustic wave device according to an example embodiment of the present invention including an acoustic multilayer film.

FIG. 22 is a partially cutaway perspective view for explaining an acoustic wave device that uses a Lamb wave.

### DETAILED DESCRIPTION OF THE EXAMPLE EMBODIMENTS

The present invention will be clarified below by describing specific example embodiments of the present invention with reference to the drawings.

The example embodiments described in this specification are illustrative, and partial substitutions or combinations of configurations is possible between different example embodiments.

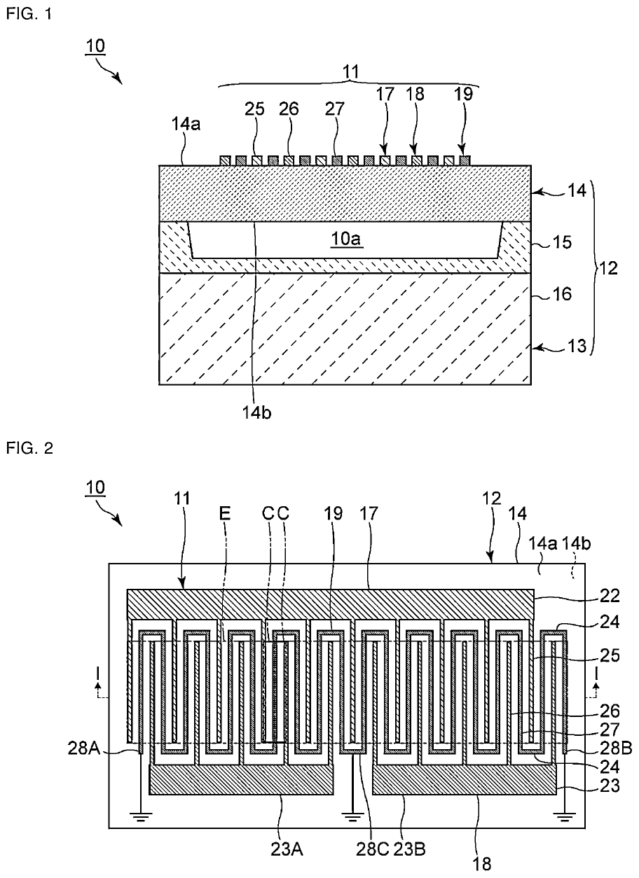

FIG. 1 is a schematic elevational cross-sectional view of an acoustic wave device according to a first example embodiment of the present invention. FIG. 2 is a schematic plan view of the acoustic wave device according to the first example embodiment. Note that FIG. 1 is a schematic cross-sectional view taken along line I-I in FIG. 2. In FIG. 2, each electrode is illustrated with hatching. In FIG. 2, a reference potential symbol is used to schematically illustrate that a reference potential electrode to be described later is connected to a reference potential. Similarly, in schematic plan views other than FIG. 2, electrodes may be hatched and the reference potential symbol may be used.

An acoustic wave device 10 illustrated in FIG. 1 is configured to use a thickness-shear mode. The acoustic wave device 10 is an acoustically coupled filter. The configuration of the acoustic wave device 10 will be described below.

The acoustic wave device 10 includes a piezoelectric substrate 12 and a functional electrode 11. The piezoelectric substrate 12 is a substrate having piezoelectricity. Specifically, the piezoelectric substrate 12 includes a support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. However, the support 13 may include the support substrate 16 only. The support 13 does not necessarily have to be provided.

The piezoelectric layer 14 includes a first main surface 14a and a second main surface 14b. The first main surface 14a and the second main surface 14b face each other. Of the first main surface 14a and the second main surface 14b, the second main surface 14b is located on the support 13 side.

As illustrated in FIG. 2, the functional electrode 11 includes a pair of comb-shaped electrodes and a reference potential electrode 19. The reference potential electrode 19 is connected to a reference potential. The pair of comb-shaped electrodes are specifically a first comb-shaped electrode 17 and a second comb-shaped electrode 18. The first comb-shaped electrode 17 is connected to an input potential. The second comb-shaped electrode 18 is connected to an output potential.

The first comb-shaped electrode 17 and the second comb-shaped electrode 18 are provided on the first main surface 14a of the piezoelectric layer 14. The first comb-shaped electrode 17 includes a first busbar 22 and a plurality of first electrode fingers 25. The plurality of first electrode fingers 25 each include one end connected to the first busbar 22. The second comb-shaped electrode 18 includes a second busbar 23 and a plurality of second electrode fingers 26. The plurality of second electrode fingers 26 each include one end connected to the second busbar 23.

The first busbar 22 and the second busbar 23 face each other. The plurality of first electrode fingers 25 and the plurality of second electrode fingers 26 are interdigitated with each other. The first electrode fingers 25 and the second electrode fingers 26 are alternately arranged in a direction orthogonal or substantially orthogonal to a direction in which the first electrode fingers 25 and the second electrode fingers 26 extend.

The reference potential electrode 19 has a meandering shape. Specifically, the reference potential electrode 19 includes a plurality of connection electrodes 24 and a plurality of third electrode fingers 27. The plurality of connection electrodes 24 and the plurality of third electrode fingers 27 are provided on the first main surface 14a of the piezoelectric layer 14. The third electrode fingers 27 adjacent to each other are connected by the connection electrodes 24. By repeating this structure, the reference potential electrode 19 is has the meandering shape.

More specifically, the plurality of third electrode fingers 27 extend parallel or substantially parallel to the plurality of first electrode fingers 25 and the plurality of second electrode fingers. The plurality of third electrode fingers 27 are provided so as to be aligned with the first electrode fingers 25 and the second electrode fingers 26 in the direction in which the first electrode fingers 25 and the second electrode fingers 26 are arranged. Thus, the first electrode fingers 25, the second electrode fingers 26, and the third electrode fingers 27 are arranged in one direction.

Hereinafter, the direction in which the first electrode fingers 25, the second electrode fingers 26, and the third electrode fingers 27 extend will be referred to as an electrode finger extending direction, and the direction orthogonal or substantially orthogonal to the electrode finger extending direction will be referred to as an electrode finger orthogonal direction. When the direction in which the first electrode fingers 25, the second electrode fingers 26, and the third electrode fingers 27 are arranged is referred to as an electrode finger arrangement direction, the electrode finger arrangement direction is parallel or substantially parallel to the electrode finger orthogonal direction. In this specification, the first electrode fingers 25, the second electrode fingers 26, and the third electrode fingers 27 may be collectively referred to simply as electrode fingers.

One of the third electrode fingers 27 is located at one end portion in the electrode finger orthogonal direction in the region where the plurality of electrode fingers are provided. The plurality of third electrode fingers 27 other than the one third electrode finger 27 are provided between the first electrode finger 25 and the second electrode finger 26. Therefore, in the present example embodiment, the plurality of third electrode fingers 27 other than the one third electrode finger 27 are provided between the first comb-shaped electrode 17 and the second comb-shaped electrode 18. On the other hand, the one third electrode finger 27 is not located between the first comb-shaped electrode 17 and the second comb-shaped electrode 18. In the present example embodiment, the one third electrode finger 27 is adjacent to only the second electrode finger 26 of the first electrode finger 25 and the second electrode finger 26.

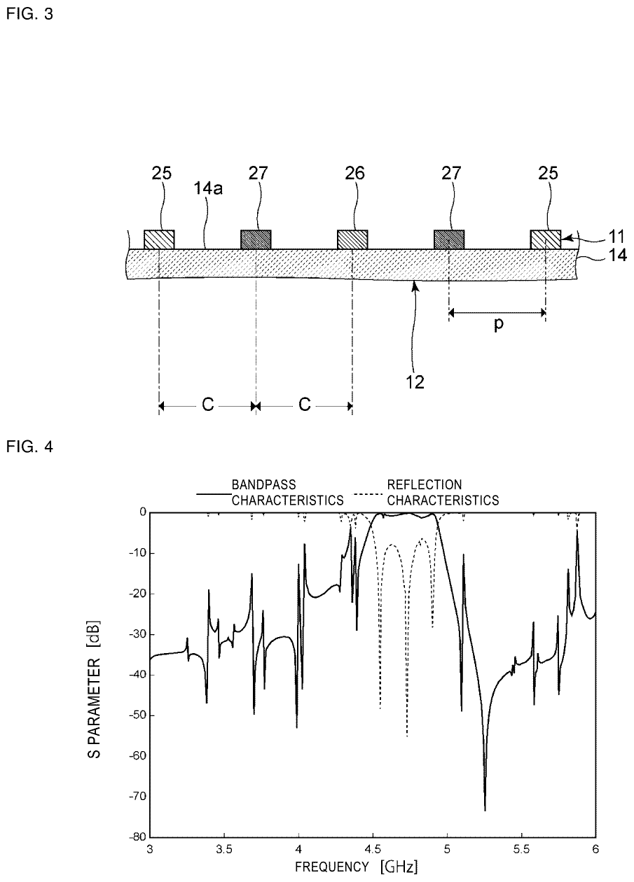

FIG. 3 is a schematic elevational cross-sectional view illustrating the vicinity of the first to third electrode fingers in the first example embodiment.

The plurality of electrode fingers are arranged as follows. Specifically, starting from the first electrode finger 25, one period includes the first electrode finger 25, the third electrode finger 27, the second electrode finger 26, and the third electrode finger 27. Therefore, the order in which the plurality of electrode fingers are arranged is the first electrode finger 25, the third electrode finger 27, the second electrode finger 26, the third electrode finger 27, the first electrode finger 25, the third electrode finger 27, the second electrode finger 26, . . . and so on. The order of the plurality of electrode fingers is represented as the order of the potentials to be connected, IN, GND, OUT, GND, IN, GND, OUT, . . . and so on, where IN represents the input potential, OUT represents the output potential, and GND represents the reference potential.

In the present example embodiment, in the region where the plurality of electrode fingers are provided, the electrode fingers located at one end portions in the electrode finger orthogonal direction are the third electrode fingers 27. In the region, the electrode fingers located at other end portions in the electrode finger orthogonal direction are the first electrode fingers 25. The electrode fingers located at the end portions in the electrode finger orthogonal direction may be any kind of the first electrode fingers 25, the second electrode fingers 26, and the third electrode fingers 27.

As illustrated in FIG. 2, the leading end portions of two adjacent third electrode fingers 27 on the first busbar 22 side or the leading end portions of two adjacent third electrode fingers 27 on the second busbar 23 side are connected to each other by the connection electrode 24. For example, among the plurality of third electrode fingers 27, the third electrode fingers 27 other than those at both ends in the electrode finger orthogonal direction include one connection electrode 24 connected to each of the leading end portions on the first busbar 22 side and the leading end portions on the second busbar 23 side. Each third electrode finger 27 is connected to a neighboring third electrode fingers 27 by each connection electrode 24. By repeating this structure, the reference potential electrode 39 has a meandering shape.

In the present example embodiment, among the plurality of third electrode fingers, the third electrode finger 27 at one end in the electrode finger orthogonal direction is not provided between the first comb-shaped electrode 17 and the second comb-shaped electrode 18. However, the entire or substantially the entire portion of the reference potential electrode 19 may be provided between the first comb-shaped electrode 17 and the second comb-shaped electrode 18. The reference potential electrode 19 only needs to be at least partially provided between the first comb-shaped electrode 17 and the second comb-shaped electrode 18.

In FIG. 2, a reference potential symbol is used to illustrate that the reference potential electrode 19 is connected to the reference potential. The portion of the reference potential electrode 19 that is connected to the reference potential is a potential connection portion. The reference potential electrode 19 includes a plurality of potential connection portions. More specifically, the reference potential electrode 19 includes a first potential connection portion 28A, a second potential connection portion 28B, and a third potential connection portion 28C. The number of the potential connection portions is not limited to three. The reference potential electrode 19 may have at least three potential connection portions.

The first potential connection portion 28A is located at the third electrode finger 27 on one end in the electrode finger orthogonal direction, among the plurality of third electrode fingers 27. More specifically, the first potential connection portion 28A is defined by a portion of the third electrode finger 27. Although not illustrated, at least one connection wiring is provided on the first main surface 14a of the piezoelectric layer 14. The first potential connection portion 28A is connected to the connection wiring. The first potential connection portion 28A is connected to the reference potential through the connection wiring.

As described above, the first potential connection portion 28A is located at the third electrode finger 27 on one end in the electrode finger orthogonal direction, among the plurality of third electrode fingers 27. On the other hand, the second potential connection portion 28B is located at the third electrode finger 27 on the other end in the electrode finger orthogonal direction, among the plurality of third electrode fingers 27. The second potential connection portion 28B is connected to the reference potential through the connection wiring.

The third potential connection portion 28C is located at the portion of the reference potential electrode 19 between two third electrode fingers 27 at both ends in the electrode finger orthogonal direction among the plurality of third electrode fingers 27. Specifically, the third potential connection portion 28C is located at the connection electrode 24 that connects two central third electrode fingers 27 in the electrode finger arrangement direction, among the plurality of third electrode fingers 27. More specifically, the connection electrode 24 connects the leading end portions of the adjacent third electrode fingers 27 on the second busbar 23 side. The third potential connection portion 28C is defined by a portion of the connection electrode 24. The third potential connection portion 28C is connected to the reference potential through the connection wiring.

The positions of the potential connection portions are not limited to those described above. In the present example embodiment, the first potential connection portion 28A, the second potential connection portion 28B, and the third potential connection portion 28C are connected to different connection wirings. However, the plurality of potential connection portions may be connected to the same connection wiring.

The connection wirings may be electrically connected to a reference potential outside the acoustic wave device 10. For example, when the acoustic wave device 10 is mounted on a mounting board, the connection wirings may be electrically connected to the mounting board through other wiring, electrode pads, a conductive bond or the like. In this case, the connection wirings may be electrically connected to the external reference potential through the mounting board or the like. The conductive bond may be, for example, a bump or a conductive adhesive.

The acoustic wave device 10 is an acoustic wave resonator configured to be able to use a thickness-shear mode bulk wave. As illustrated in FIG. 2, the acoustic wave device 10 includes a plurality of excitation regions C. In the plurality of excitation regions C, the thickness-shear mode bulk waves and acoustic waves in other modes are excited. FIG. 2 illustrates only two of the plurality of excitation regions C.

Some of the plurality of excitation regions C are regions where the adjacent first electrode finger 25 and third electrode finger 27 overlap when viewed from the electrode finger orthogonal direction, and also regions between the centers of the adjacent first electrode finger 25 and third electrode finger 27. The rest of the excitation regions C are regions where the adjacent second electrode finger 26 and third electrode finger 27 overlap when viewed from the electrode finger orthogonal direction, and also regions between the centers of the adjacent second electrode finger 26 and third electrode finger 27. These excitation regions C are arranged in the electrode finger orthogonal direction. It should be noted that the excitation regions C are regions of the piezoelectric layer 14, defined based on a configuration of the functional electrode 11.

The present example embodiment has the following configuration. 1) The third electrode finger 27 of the reference potential electrode 19 is provided between the first electrode finger 25 of the first comb-shaped electrode 17 and the second electrode finger 26 of the second comb-shaped electrode 18. 2) The reference potential electrode 19 includes at least three potential connection portions. This makes it possible to achieve miniaturization of a filter device and reduce the electrical resistance of the acoustic wave device 10 when the acoustic wave device 10 is used in the filter device. This will be described below.

FIG. 4 illustrates an example of bandpass characteristics and reflection characteristics of the acoustic wave device 10.

FIG. 4 is a graph illustrating bandpass characteristics and reflection characteristics of the acoustic wave device according to the first example embodiment. FIG. 4 illustrates the results of a finite element method (FEM) simulation.

As illustrated in FIG. 4, it can be seen that a filter waveform can be suitably obtained even with a single acoustic wave device 10. The acoustic wave device 10 is an acoustically coupled filter. More specifically, as illustrated in FIG. 2, the acoustic wave device 10 includes an excitation region C located between the centers of the adjacent first electrode finger 25 and third electrode finger 27, and an excitation region C located between the centers of the adjacent second electrode finger 26 and third electrode finger 27. In these excitation regions C, acoustic waves in a plurality of modes including a thickness-shear mode bulk wave are excited. By coupling these modes, a filter waveform can be suitably obtained even with a single acoustic wave device 10.

When the acoustic wave device 10 is used as an acoustic wave resonator in a filter device, a filter waveform can be suitably obtained even with one or a small number of acoustic wave resonators that define the filter device. This makes it possible to achieve miniaturization of the filter device.

In addition, as illustrated in FIG. 2, in the present example embodiment, the reference potential electrode 19 includes three potential connection portions. This makes it possible to reduce the electrical resistance of the reference potential electrode 19, and thus to reduce the electrical resistance of the acoustic wave device 10. This will be described in detail below by comparing the present example embodiment with a reference example.

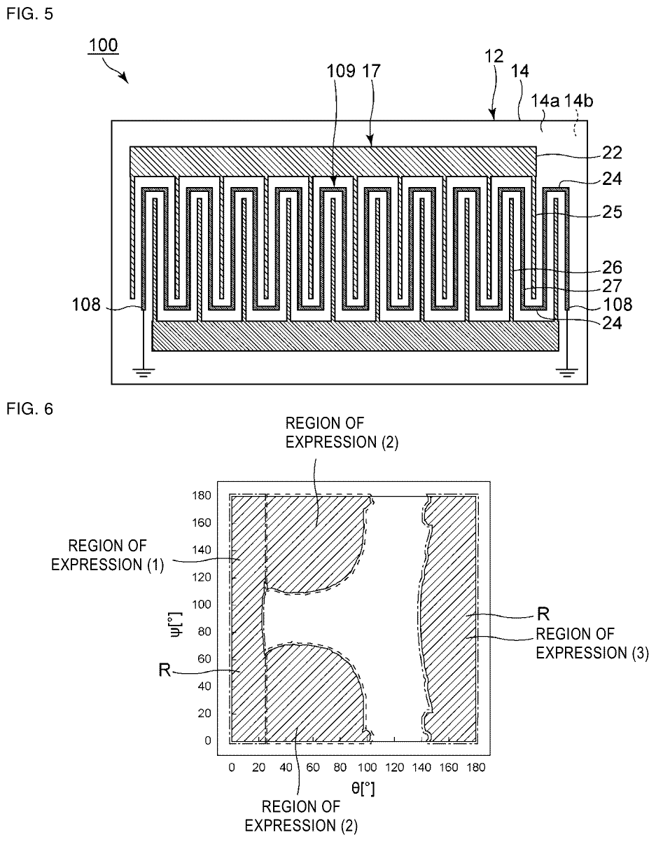

The reference example illustrated in FIG. 5 differs from the first example embodiment in the configuration of a reference potential electrode 109. Specifically, the reference potential electrode 109 includes only two potential connection portions 108. As in the first example embodiment, the reference potential electrode 109 includes a plurality of connection electrodes 24 and a plurality of third electrode fingers 27. The reference potential electrode 109 has a meandering shape. The two potential connection portions 108 are located on the two third electrode fingers 27 at both ends in the electrode finger orthogonal direction. An acoustic wave device 100 of the reference example includes a pair of comb-shaped electrodes. A portion of the reference potential electrode 109 is provided between the pair of comb-shaped electrodes.

The reference potential electrode 109 includes the plurality of connection electrodes 24 and the plurality of third electrode fingers 27 between both potential connection portions 108. Therefore, the length of the portion of the reference potential electrode 109 between the two potential connection portions 108 is long. Furthermore, more than one third electrode finger 27 and the plurality of connection electrodes 24 are provided between the pair of comb-shaped electrodes. Therefore, the width of the plurality of third electrode fingers 27 and the plurality of connection electrodes 24 is narrow. Therefore, the electrical resistance of the reference potential electrode 109 is high.

The length of the reference potential electrode 109 is the sum of the length of the plurality of third electrode fingers 27 and the length of the plurality of connection electrodes 24. The length of the third electrode fingers 27 is the dimension of the third electrode fingers 27 along the electrode finger extending direction. The length of the connection electrodes 24 is the dimension along the direction in which the connection electrodes 24 extend. In the reference example and the first example embodiment, the direction in which the connection electrode 24 extends is parallel or substantially parallel to the electrode finger orthogonal direction. The width of the third electrode finger 27 is the dimension of the third electrode finger 27 along the electrode finger orthogonal direction. The width of the connection electrode 24 is the dimension along the direction orthogonal or substantially orthogonal to the direction in which the connection electrode 24 extends. The above lengths and widths are defined similarly for the reference potential electrode of the present invention.

In the first example embodiment illustrated in FIG. 2, compared to the reference example, the reference potential electrode 19 includes three potential connection portions. Therefore, at least one potential connection portion is located in a portion of the reference potential electrode 19 between two third electrode fingers 27 at both ends in the electrode finger orthogonal direction, among the plurality of third electrode fingers 27. This makes it possible to shorten the length of the portion of the reference potential electrode 19 between the potential connection portions.

More specifically, the reference potential electrode 19 includes two portions between the potential connection portions. One portion between the potential connection portions is the portion between the first potential connection portion 28A and the third potential connection portion 28C. The other portion between the potential connection portions is the portion between the second potential connection portion 28B and the third potential connection portion 28C. This makes it possible to shorten the length of the portion between the potential connection portions, compared to the case where there is only one portion between the potential connection portions. This makes it possible to reduce the electrical resistance of the reference potential electrode 19, and thus to reduce the electrical resistance of the acoustic wave device 10.

The electrical resistance of the acoustic wave device 10 here is a series resistance. The series resistance of the acoustic wave device 10 is the electrical resistance of the acoustic wave device 10 when the acoustic wave device 10 is used in a filter device and is connected in series with another element.

The configuration of the first example embodiment will be described in more detail below.

As illustrated in FIG. 2, two third electrode fingers 27 at both ends in the electrode finger orthogonal direction, among the plurality of third electrode fingers 27, are located at outer side portions in the electrode finger orthogonal direction outside both end portions of the second comb-shaped electrode 18 in the electrode finger orthogonal direction. Each connection wiring connected to the first potential connection portion 28A and the second potential connection portion 28B passes the outer side portions in the electrode finger orthogonal direction outside the both end portions of the second comb-shaped electrode 18.

On the other hand, the third potential connection portion 28C is located at the inner side portion in the electrode finger orthogonal direction inside both end portions of the first comb-shaped electrode 17 in the electrode finger orthogonal direction and both end portions of the second comb-shaped electrode 18 in the electrode finger orthogonal direction. Here, in the first example embodiment, the second busbar 23 is divided into two split busbar portions 23A and 23B. The split busbar portion 23A and the split busbar portion 23B face each other across a gap in the electrode finger orthogonal direction. The connection wiring connected to the third potential connection portion 28C passes between the split busbar portion 23A and the split busbar portion 23B, and is connected to the reference potential.

The position of each potential connection portion is not particularly limited. However, it is preferable that the first potential connection portion 28A and the potential connection portion 28B are located on two third electrode fingers 27 at both ends in the electrode finger orthogonal direction, among the plurality of third electrode fingers 27. This makes it possible to easily connect the connection wiring of the first potential connection portion 28A and the second potential connection portion 28B to the reference potential.

The connection wiring includes a portion located on the outer side portion of the first comb-shaped electrode 17 and the second comb-shaped electrode 18, and does not contribute to the excitation of the acoustic wave. This makes it possible to increase the width of the connection wiring. Therefore, the electrical resistance of the connection wiring can be easily reduced.

As illustrated in FIG. 1, the support 13 includes the support substrate 16 and the insulating layer 15. The piezoelectric substrate 12 is a multilayer body including the support substrate 16, the insulating layer 15, and the piezoelectric layer 14. Specifically, the piezoelectric layer 14 and the support 13 overlap when viewed from the direction in which the first main surface 14a and the second main surface 14b of the piezoelectric layer 14 face each other.

Examples of the material of the support substrate 16 include a semiconductor such as silicon, ceramics such as aluminum oxide, and the like. The insulating layer 15 can be made of an appropriate dielectric such as, for example, silicon oxide or tantalum oxide. The piezoelectric layer 14 may be, for example, a lithium niobate layer such as a LiNbO₃ layer or a lithium tantalate layer such as a LiTaO₃ layer.

The insulating layer 15 includes a recess portion. The piezoelectric layer 14 is provided on the insulating layer 15 so as to close the recess portion. A hollow portion is thus provided. This hollow portion is a cavity 10a. In the first example embodiment, the support 13 and the piezoelectric layer 14 are disposed so that a portion of the support 13 and a portion of the piezoelectric layer 14 face each other across the cavity 10a. However, the recess portion in the support 13 may be provided across the insulating layer 15 and the support substrate 16. Alternatively, a recess portion provided only in the support substrate 16 may be closed by the insulating layer 15. The recess portion may be provided in the piezoelectric layer 14. The cavity 10a may be a through-hole provided in the support 13.

The cavity 10a is an acoustic reflection portion. The acoustic reflection portion can effectively confine the energy of the acoustic wave to the piezoelectric layer 14 side. The acoustic reflection portion may be provided at a position on the support 13 that overlaps at least a portion of the functional electrode 11 in plan view. More specifically, the first electrode finger 25, the second electrode finger 26, and the third electrode finger 27 may each at least partially overlap with the acoustic reflection portion in plan view. In plan view, a plurality of excitation regions C preferably overlap with the acoustic reflection portion.

In this specification, a plan view refers to a view along the lamination direction of the support 13 and the piezoelectric layer 14 from a direction corresponding to the upper side in FIG. 1. In FIG. 1, for example, of the support substrate 16 side and the piezoelectric layer 14 side, the piezoelectric layer 14 side is the upper side. Furthermore, in this specification, the plan view is synonymous with a view from a main surface facing direction. The main surface facing direction is a direction in which the first main surface 14a and the second main surface 14b of the piezoelectric layer 14 face each other. More specifically, the main surface facing direction is, for example, a normal or substantially normal direction of the first main surface 14a.

The acoustic reflection portion may be an acoustic reflection film such as an acoustic multilayer film, which will be described later. For example, the acoustic reflection film may be provided on the surface of the support.

In the first example embodiment, the center-to-center distance between a plurality of pairs of first electrode fingers 25 and third electrode fingers 27 adjacent to each other is the same as the center-to-center distance between a plurality of pairs of second electrode fingers 26 and third electrode fingers 27 adjacent to each other. In this case, for example, d/p is preferably less than or equal to about 0.5, and more preferably less than or equal to about 0.24, where d is the thickness of the piezoelectric layer 14 and p is the center-to-center distance between adjacent electrode fingers. This allows for better excitation of the thickness-shear mode bulk wave.

However, the center-to-center distance between the adjacent first electrode finger 25 and third electrode finger 27 and the center-to-center distance between the adjacent second electrode finger 26 and third electrode finger 27 do not have to be constant. In this case, it is preferable that p is the longest distance of the center-to-center distance between the adjacent first electrode finger 25 and third electrode finger 27 and the center-to-center distance between the adjacent second electrode finger 26 and third electrode finger 27. In this case, for example, d/p is preferably less than or equal to about 0.5, and more preferably less than or equal to about 0.24. The acoustic wave device does not necessarily have to be configured to be able to use the thickness-shear mode.

As illustrated in FIG. 2, when viewed from the electrode finger orthogonal direction, the region where the adjacent first electrode finger 25 and third electrode finger 27 or the adjacent second electrode finger 26 and third electrode finger 27 overlap each other is an intersection region E. The intersection region E includes a plurality of excitation regions C. The acoustic wave device according to an example embodiment of the present invention may be configured to be able to use a plate wave. In this case, the excitation region is the intersection region E. The intersection region E is region of the piezoelectric layer 14, defined based on configuration of the functional electrode 11.

The configuration of the functional electrode 11, except for the reference potential electrode 19, is the same or substantially the same as that of an interdigital transducer (IDT) electrode. The intersection region E can also be a region where the adjacent first electrode finger 25 and second electrode finger 26 overlap each other when viewed from the electrode finger orthogonal direction.

Each connection electrode 24 of the reference potential electrode 19 is provided on the outer side portion of the excitation region C in the electrode finger extending direction. In the first example embodiment, all of the adjacent third electrode fingers 27 of the reference potential electrode 19 are connected to each other by the connection electrodes 24. However, all of the adjacent third electrode fingers 27 do not necessarily have to be connected to each other by the connection electrodes 24.

The second busbar 23 includes a split busbar portion 23A and a split busbar portion 23B. On the other hand, the first busbar 22 is not divided. The configurations of the first busbar 22 and the second busbar 23 are not limited to those described above. However, it is preferable that at least one of the first busbar 22 and the second busbar 23 is divided and includes a plurality of split busbar portions. This allows for a configuration in which the connection wiring connected to the potential connection portion passes between the split busbar portions. Therefore, the connection wiring can be easily connected to the reference potential.

In the first example embodiment, the piezoelectric layer 14 is, for example, the lithium niobate layer. Specifically, for example, a LiNbO₃ of a rotated Y-cut is used as the piezoelectric layer 14. In this case, the fractional band width of the acoustic wave device 10 depends on the Euler angles (φ, θ, ψ) of the lithium niobate used in the piezoelectric layer 14. The fractional band width is expressed by (|fa−fr|/fr)×100 [%], where fr is the resonant frequency and fa is the anti-resonant frequency.

The relationship between the fractional band width of the acoustic wave device 10 and the Euler angles (φ, θ, ψ) of the piezoelectric layer 14 when d/p is infinitely close to 0 is derived. Note that φ in the Euler angles is set to 0°.

FIG. 6 is a diagram illustrating a map of a fractional band width with respect to the Euler angles (0°, θ, ψ) of LiNbO₃ when d/p is infinitely close to 0.

A hatched region R in FIG. 6 is, for example, a region where the fractional band width of at least more than or equal to about 2% is obtained. The range of the region R is approximated by the following Expressions (1), (2), and (3). When φ in the Euler angles (φ, θ, ψ) is within the range of about 0°±10°, the relationship between θ and ψ and the fractional band width is the same as that illustrated in FIG. 6. Also in the case where the piezoelectric layer 14 is a lithium tantalate layer, when φ is within the range of 0°±100, the relationship between θ and ψ and the fractional band width is the same or substantially the same as that illustrated in FIG. 6.

(within the range of 0°±10°, 0° to 25°, any ψ) Expression (1)

(within the range of 0°±10°, 25° to 100°, 75° [(1−(θ−50)²/2500)]^{1/2} or 1800-75° [(1−(θ−50)²/2500)]^{1/2} to 180°) Expression (2)

(within the range of 0°±10°, 180°−40° [(1−(ψ−90)²/8100)]^{1/2} to 180°, any ψ) Expression (3)

It is preferable that the Euler angles are within the range of Expression (1), Expression (2), or Expression (3). This allows the fractional band width to be sufficiently widened, thus making it possible to suitably use the acoustic wave device 10 in a filter device.

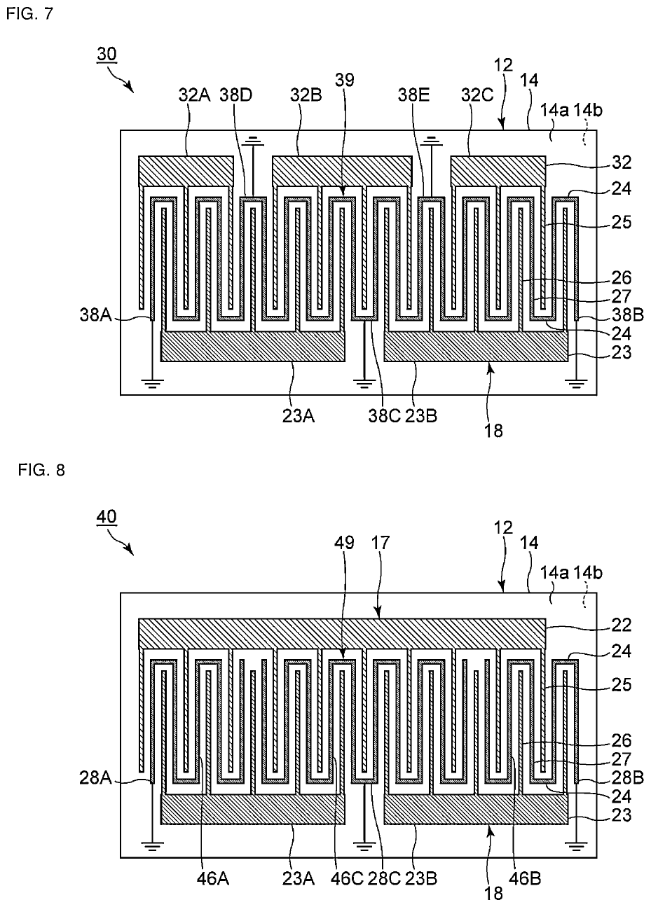

FIG. 7 is a schematic plan view of an acoustic wave device according to a second example embodiment of the present invention.

The present example embodiment differs from the first example embodiment in that the reference potential electrode 39 includes five potential connection portions. The present example embodiment also differs from the first example embodiment in that a first busbar 32 is divided into three split busbar portions 32A, 32B, and 32C. The split busbar portions 32A and 32B face each other across a gap in the electrode finger orthogonal direction. The split busbar portions 32B and 32C face each other across a gap in the electrode finger orthogonal direction. Otherwise, an acoustic wave device 30 of the present example embodiment has the same or substantially the same configuration as that of the acoustic wave device 10 of the first example embodiment. A second busbar 23 includes two split busbar portions 23A and 23B, as in the first example embodiment.

The five potential connection portions of the reference potential electrode 39 are specifically a first potential connection portion 38A, a second potential connection portion 38B, and three third potential connection portions. The three third potential connection portions are specifically a third potential connection portion 38C, a third potential connection portion 38D, and a third potential connection portion 38E. The first potential connection portion 38A and the second potential connection portion 38B are located on the two third electrode fingers 27 at both ends in the electrode finger orthogonal direction, among the plurality of third electrode fingers 27.

On the other hand, the three third potential connection portions are located in a portion of the reference potential electrode 39 between the two third electrode fingers 27. More specifically, the third potential connection portion 38C is located at the connection electrode 24 that connects the leading end portions of the adjacent third electrode fingers 27 on the second busbar 23 side. On the other hand, the third potential connection portion 38D and the third potential connection portion 38E are each located at the connection electrode 24 that connects the leading end portions of the adjacent third electrode fingers 27 on the first busbar 32 side.

The third potential connection portion 38C is located between the third potential connection portion 38D and the third potential connection portion 38E. More specifically, the third potential connection portion 38C is located at the connection electrode 24 that connects the two central third electrode fingers 27 in the electrode finger orthogonal direction among the plurality of third electrode fingers 27. However, the position of each potential connection portion is not limited to the above.

The five potential connection portions are each connected to a reference potential through a connection wiring. Specifically, each connection wiring connected to the first potential connection portion 38A and the second potential connection portion 38B passes the outer side portions in the electrode finger orthogonal direction than the both end portions of the second comb-shaped electrode 18 in the electrode finger orthogonal direction.

The connection wiring connected to the third potential connection portion 38D passes between the split busbar portion 32A and the split busbar portion 32B of the first busbar 32. The connection wiring connected to the third potential connection portion 38E passes between the split busbar portion 32B and the split busbar portion 32C of the first busbar 32.

In the present example embodiment, the reference potential electrode 39 includes the five potential connection portions. This makes it possible to effectively shorten the length of the portion between the potential connection portions. This makes it possible to effectively reduce the electrical resistance of the reference potential electrode 39, and thus to effectively reduce the electrical resistance of the acoustic wave device 30.

FIG. 8 is a schematic plan view of an acoustic wave device according to a third example embodiment of the present invention.

The present example embodiment differs from the first example embodiment in that, in a reference potential electrode 49, some of the adjacent third electrode fingers 27 are not connected to each other by connection electrodes 24. Otherwise, an acoustic wave device 40 of the present example embodiment has the same or substantially the same configuration as that of the acoustic wave device 10 of the first example embodiment.

The reference potential electrode 49 includes a plurality of electrode portions. The plurality of electrode portions in the present example embodiment are specifically a first electrode portion 46A, a second electrode portion 46B, and a third electrode portion 46C. Each electrode portion includes a plurality of third electrode fingers 27 and at least one connection electrode 24. The electrode portions are not connected to each other by the connection electrode 24. In other words, the reference potential electrode 49 is divided into the plurality of electrode portions.

Each electrode portion includes a potential connection portion. Specifically, the first electrode portion 46A is located at one end of the plurality of electrode portions in the electrode finger orthogonal direction. The first electrode portion 46A includes a first potential connection portion 28A. The second electrode portion 46B is located at the other end of the plurality of electrode portions in the electrode finger orthogonal direction. The second electrode portion 46B includes a second potential connection portion 28B. The third electrode portion 46C is located between the first electrode portion 46A and the second electrode portion 46B. The third electrode portion 46C includes a third potential connection portion 28C.

Each electrode portion is connected to a reference potential at each potential connection portion. More specifically, each electrode portion is connected to the reference potential through a connection wiring connected to each potential connection portion.

Each electrode portion includes an end portion in the reference potential electrode 49. The end portion of the electrode portion is the end portion of the third electrode finger 27 that is not connected to the connection electrode 24 or the connection wiring.

In the present example embodiment, the reference potential electrode 49 is divided into a plurality of electrode portions. Therefore, the length of each electrode portion is shorter than the total length of all the third electrode fingers 27 and all of the connection electrodes 24 of the reference potential electrode 49. Therefore, in each electrode portion, the length from the potential connection portion to the end portion of the electrode portion is short. This makes it possible to effectively reduce the electrical resistance of the reference potential electrode 49, and thus to effectively reduce the electrical resistance of the acoustic wave device 40. The length of the electrode portion is the total length of all the third electrode fingers 27 and all of the connection electrodes 24 in the electrode portion.

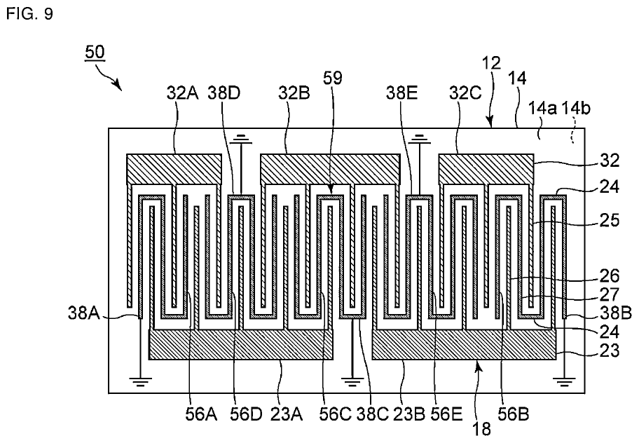

FIG. 9 is a schematic plan view of an acoustic wave device according to a fourth example embodiment of the present invention.

The present example embodiment differs from the second example embodiment in that, in a reference potential electrode 59, some of adjacent third electrode fingers 27 are not connected to each other by connection electrodes 24. Specifically, the reference potential electrode 59 is divided into five electrode portions. Otherwise, an acoustic wave device 50 of the present example embodiment has the same or substantially the same configuration as that of the acoustic wave device 30 of the second example embodiment.

A first busbar 32 and a second busbar 23 each include a plurality of split busbar portions, as in the second example embodiment. More specifically, the first busbar 32 includes three split busbar portions 32A, 32B, and 32C. The second busbar 23 includes two split busbar portions 23A and 23B.

The reference potential electrode 59 includes five potential connection portions arranged in the same or substantially the same manner as in the second example embodiment.

The five potential connection portions are specifically a first potential connection portion 38A, a second potential connection portion 38B, and three third potential connection portions. The three third potential connection portions are specifically a third potential connection portion 38C, a third potential connection portion 38D, and a third potential connection portion 38E.

In the present example embodiment, the reference potential electrode 59 includes five electrode portions. The five electrode portions in the present example embodiment are specifically a first electrode portion 56A, a second electrode portion 56B, and three third electrode portions. The three third electrode portions are specifically a third electrode portion 56C, a third electrode portion 56D, and a third electrode portion 56E.

The first electrode portion 56A is located at one end of the plurality of electrode portions in the electrode finger orthogonal direction. The first electrode portion 56A has a first potential connection portion 38A. The second electrode portion 56B is located at the other end of the plurality of electrode portions in the electrode finger orthogonal direction. The second electrode portion 56B has a second potential connection portion 38B.

The third electrode portion 56C, the third electrode portion 56D, and the third electrode portion 56E are located between the first electrode portion 56A and the second electrode portion 56B. The third electrode portion 56C is also located between the third electrode portion 56D and the third electrode portion 56E. The third electrode portion 56C has a third potential connection portion 38C. The third electrode portion 56D has a third potential connection portion 38D. The third electrode portion 56E has a third potential connection portion 38E.

Each electrode portion is connected to a reference potential through a connection wiring connected to each potential connection portion. Specifically, each connection wiring connected to the first potential connection portion 38A and the second potential connection portion 38B passes the outer side portions in the electrode finger orthogonal direction outside the both end portions of the second comb-shaped electrode 18 in the electrode finger orthogonal direction.

The connection wiring connected to the third potential connection portion 38C passes between the split busbar portion 23A and the split busbar portion 23B of the second busbar 23. The connection wiring connected to the third potential connection portion 38D passes between the split busbar portion 32A and the split busbar portion 32B of the first busbar 32. The connection wiring connected to the third potential connection portion 38E passes between the split busbar portion 32B and the split busbar portion 32C of the first busbar 32.

The number of the electrode portions of the reference potential electrode 59 and the number of the potential connection portions are not limited to the above. Similarly, the number of divisions of the first busbar 32 and the second busbar 23 are also not limited to the above.

In the present example embodiment, the reference potential electrode 59 is divided into a plurality of electrode portions. Therefore, the length of each electrode portion is shorter than the total length of all the third electrode fingers 27 and all the connection electrodes 24 of the reference potential electrode 59. Therefore, in each electrode portion, the length from the potential connection portion to the end portion of the electrode portion is short. This makes it possible to effectively reduce the electrical resistance of the reference potential electrode 59, and thus to effectively reduce the electrical resistance of the acoustic wave device 50.

The thickness-shear mode will be described in detail below using an example where the functional electrode is an IDT electrode. The IDT electrode includes no third electrode fingers. The “electrode” in the IDT electrode described below corresponds to the electrode finger. A support in the following example corresponds to the support substrate. The reference potential may be hereinafter referred to as a ground potential.

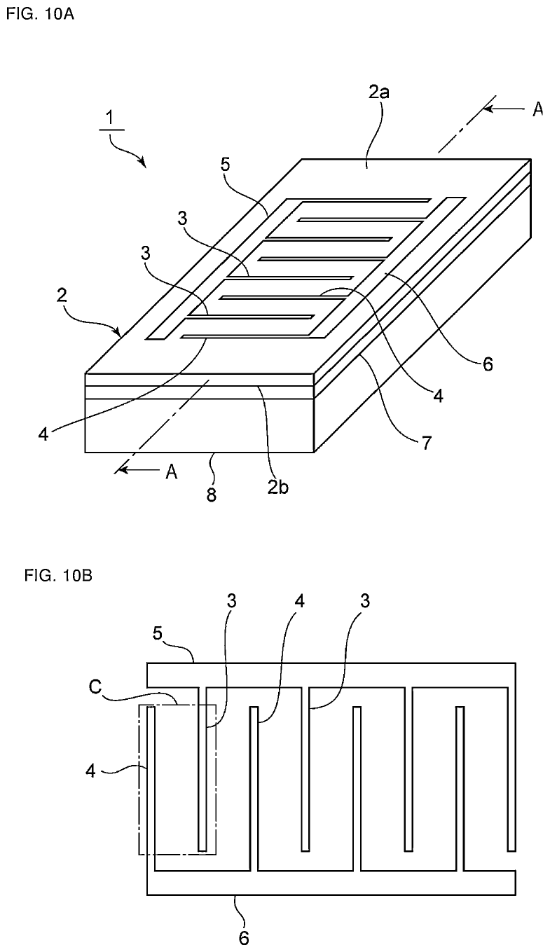

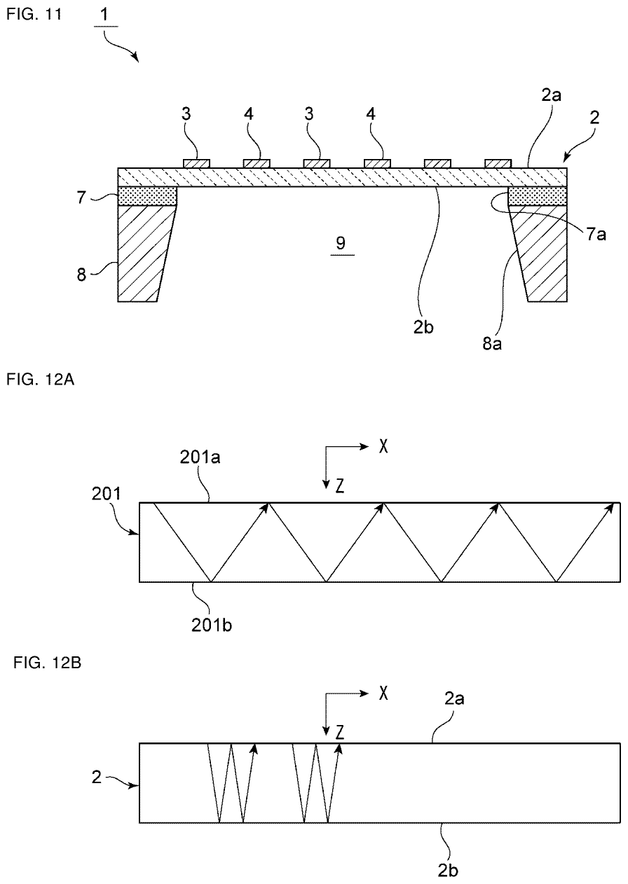

FIG. 10A is a schematic perspective view illustrating an appearance of an acoustic wave device that uses a thickness-shear mode bulk wave. FIG. 10B is a plan view illustrating an electrode structure on a piezoelectric layer. FIG. 11 is a cross-sectional view of a portion taken along line A-A in FIG. 10A.

An acoustic wave device 1 includes a piezoelectric layer 2 made of, for example, LiNbO₃. The piezoelectric layer 2 may be made of, for example, LiTaO₃. The cut-angle of LiNbO₃ or LiTaO₃ is a Z-cut in the present example embodiment, but may be a rotated Y-cut or X-cut. The thickness of the piezoelectric layer 2 is not particularly limited, but is, for example, preferably more than or equal to about 40 nm and less than or equal to about 1000 nm, and more preferably more than or equal to about 50 nm and less than or equal to about 1000 nm in order to effectively excite a thickness-shear mode. The piezoelectric layer 2 includes a first main surface 2a and a second main surface 2b facing each other. An electrode 3 and an electrode 4 are provided on the first main surface 2a. Here, the electrode 3 is an example of a “first electrode” and the electrode 4 is an example of a “second electrode”. In FIGS. 10A and 10B, a plurality of the electrodes 3 are connected to a first busbar 5. A plurality of the electrodes 4 are connected to a second busbar 6. The plurality of electrodes 3 and the plurality of electrodes 4 are interdigitated with each other. The electrode 3 and the electrode 4 have a rectangular or substantially rectangular shape and have a length direction. In a direction orthogonal or substantially orthogonal to the length direction, the electrode 3 and the electrode 4 adjacent thereto face each other. The length direction of the electrodes 3 and 4 and the direction orthogonal or substantially orthogonal to the length direction of the electrodes 3 and 4 each are a direction intersecting a thickness direction of the piezoelectric layer 2. Therefore, it can also be said that the electrode 3 and the electrode 4 adjacent thereto face each other in the direction intersecting the thickness direction of the piezoelectric layer 2. The length direction of the electrodes 3 and 4 may be replaced with the direction orthogonal or substantially orthogonal to the length direction of the electrodes 3 and 4 illustrated in FIGS. 10A and 10B. That is, the electrodes 3 and 4 may extend in the direction in which the first busbar 5 and the second busbar 6 extend in FIGS. 10A and 10B. In this case, the first busbar 5 and the second busbar 6 extend in the direction in which the electrodes 3 and 4 extend in FIGS. 10A and 10B. A plurality of pairs of structures in which the electrode 3 connected to one potential and the electrode 4 connected to the other potential are adjacent to each other are provided in the direction orthogonal or substantially orthogonal to the length direction of the electrodes 3 and 4 described above. Here, the electrode 3 and the electrode 4 being adjacent to each other refers not to a case where the electrode 3 and the electrode 4 are arranged so as to be in direct contact with each other but to a case where the electrode 3 and the electrode 4 are arranged with an interval therebetween. When the electrode 3 and the electrode 4 are adjacent to each other, an electrode connected to a hot electrode or a ground electrode, including the other electrodes 3 and 4, is not arranged between the electrode 3 and the electrode 4. The number of pairs need not be integer pairs, but may be, for example, 1.5 pairs, 2.5 pairs, or the like. The center-to-center distance between the electrodes 3 and 4, that is, the pitch is, for example, preferably in the range of more than or equal to about 1 μm and less than or equal to about 10 μm. In addition, the width of the electrodes 3 and 4, that is, the dimension of the electrodes 3 and 4 in their facing direction, is, for example, preferably in the range of more than or equal to about 50 nm and less than or equal to about 1000 nm, and more preferably in the range of more than or equal to about 150 nm and less than or equal to about 1000 nm. The center-to-center distance between the electrodes 3 and 4 is a distance connecting the center of the dimension (width dimension) of the electrode 3 in the direction orthogonal or substantially orthogonal to the length direction of the electrode 3 and the center of the dimension (width dimension) of the electrode 4 in the direction orthogonal or substantially orthogonal to the length direction of the electrode 4.

In the acoustic wave device 1, since the Z-cut piezoelectric layer is used, the direction orthogonal or substantially orthogonal to the length direction of the electrodes 3 and 4 is a direction orthogonal or substantially orthogonal to the polarization direction of the piezoelectric layer 2. This does not apply when a piezoelectric body of another cut-angle is used as the piezoelectric layer 2. Here, the term “orthogonal” is not limited to strictly orthogonal but may be substantially orthogonal (an angle between the direction orthogonal to the length direction of the electrodes 3 and 4 and the polarization direction is, for example, about 90°+) 10°.

A support 8 is laminated on the second main surface 2b side of the piezoelectric layer 2 with an insulating layer 7 interposed therebetween. The insulating layer 7 and the support 8 have a frame shape and include through-holes 7a and 8a as illustrated in FIG. 11. A cavity 9 is thus provided. The cavity 9 is provided so as not to interfere with the vibration of an excitation region C of the piezoelectric layer 2. Therefore, the support 8 is laminated on the second main surface 2b with the insulating layer 7 interposed therebetween at a position not overlapping with a portion where at least a pair of electrodes 3 and 4 are provided. The insulating layer 7 need not be provided. Therefore, the support 8 can be directly or indirectly laminated on the second main surface 2b of the piezoelectric layer 2.

The insulating layer 7 is made of, for example, silicon oxide. However, the insulating layer 7 can be made of an appropriate insulating material such as, for example, silicon oxynitride or alumina in addition to silicon oxide. The support 8 is made of, for example, Si. The plane orientation of the surface of Si on the piezoelectric layer 2 side may be (100), (110), or (111). Preferably, for example, high-resistance Si having the support 8 of more than or equal to about 4 kΩ cm is preferable. However, the support 8 can also be made using an appropriate insulating material or semiconductor material. Examples of the material of the support 8 include piezoelectric bodies such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, semiconductors such as gallium nitride, and the like.

The plurality of electrodes 3 and 4 and the first and second busbars 5 and 6 are made of an appropriate metal or alloy such as, for example, Al or an AlCu alloy. In the acoustic wave device 1, the electrodes 3 and 4 and the first and second busbars 5 and 6 have, for example, a structure in which an Al film is laminated on a Ti film. A close contact layer other than the Ti film may be used.

At the time of driving, an AC voltage is applied between the plurality of electrodes 3 and the plurality of electrodes 4. More specifically, an AC voltage is applied between the first busbar 5 and the second busbar 6. This makes it possible to obtain resonance characteristics using a bulk wave in the thickness-shear mode excited in the piezoelectric layer 2. In the acoustic wave device 1, for example, d/p is less than or equal to about 0.5, where d is the thickness of the piezoelectric layer 2, and p is the center-to-center distance between any adjacent electrodes 3 and 4 of the plurality of pairs of electrodes 3 and 4. Therefore, the bulk wave in the thickness-shear mode is effectively excited, and good resonance characteristics can be obtained. More preferably, for example, d/p is less than or equal to about 0.24, in which case even better resonance characteristics can be obtained.

Since the acoustic wave device 1 has the configuration described above, even when the number of pairs of the electrodes 3 and 4 is reduced in an attempt for miniaturization, Q value is not easily reduced. This is because the propagation loss is small even if the number of electrode fingers in the reflectors on both sides is reduced. In addition, the reason why the number of electrode fingers can be reduced is that the bulk wave in the thickness-shear mode is used. The difference between a Lamb wave used in an acoustic wave device and the thickness-shear mode bulk wave described above will be described with reference to FIGS. 12A and 12B.

FIG. 12A is a schematic elevational cross-sectional view for explaining a Lamb wave propagating through a piezoelectric film of an acoustic wave device as described in Japanese Unexamined Patent Application Publication No. 2012-257019. As illustrated in FIG. 12A, a wave propagates through a piezoelectric film 201 as indicated by arrows. Here, the piezoelectric film 201 includes a first main surface 201a and a second main surface 201b, which face each other, and a thickness direction connecting the first main surface 201a and the second main surface 201b is the Z direction. The X direction is a direction in which electrode fingers of an IDT electrode are arranged. As illustrated in FIG. 12A, the Lamb wave propagates in the X direction. Although the piezoelectric film 201 vibrates as a whole because of the plate wave, since the wave propagates in the X direction, reflectors are arranged on both sides to obtain resonance characteristics. Therefore, a propagation loss of waves occurs, and the Q value decreases when the size is reduced, that is, when the number of pairs of electrode fingers is reduced.

On the other hand, as illustrated in FIG. 12B, in the acoustic wave device 1, since the vibration displacement is in the thickness-shear direction, the wave substantially propagates in the direction connecting the first main surface 2a and the second main surface 2b of the piezoelectric layer 2, that is, the Z direction, and resonates. Specifically, the X direction component of the wave is significantly smaller than the Z direction component. Since resonance characteristics are obtained by the propagation of the wave in the Z direction, propagation loss does not easily occur even when the number of electrode fingers of the reflector is reduced. Furthermore, even when the number of pairs of electrodes consisting of the electrodes 3 and 4 is reduced in an attempt to achieve miniaturization, the Q value is not easily reduced.

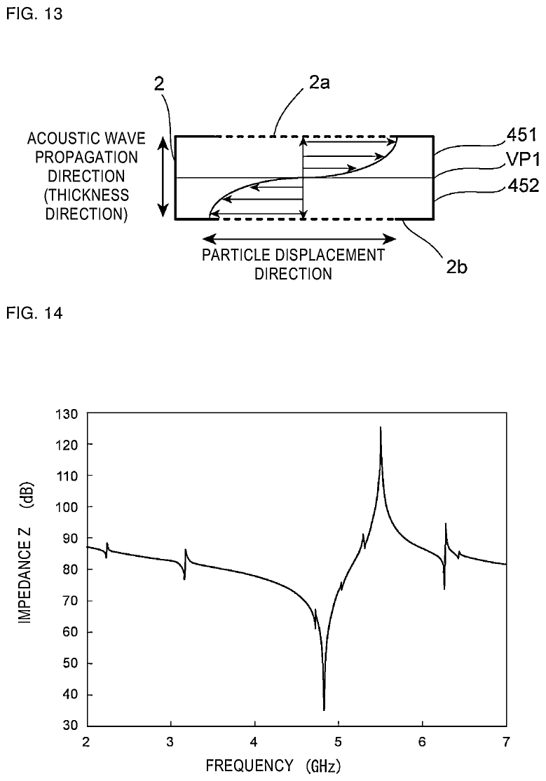

As illustrated in FIG. 13, the amplitude direction of the bulk wave in the thickness-shear mode in a first region 451 included in the excitation region C of the piezoelectric layer 2 is the opposite in a second region 452 included in the excitation region C. FIG. 13 schematically illustrates a bulk wave when a voltage is applied between the electrode 3 and the electrode 4 so that the electrode 4 has a higher potential than the electrode 3. The first region 451 is a region between the first main surface 2a and a virtual plane VP1 that is orthogonal or substantially orthogonal to the thickness direction of the piezoelectric layer 2 and divides the piezoelectric layer 2 into two portions in the excitation region C. The second region 452 is a region between the virtual plane VP1 and the second main surface 2b in the excitation region C.

As described above, in the acoustic wave device 1, at least a pair of electrodes including the electrode 3 and the electrode 4 are arranged. However, since waves are not propagated in the X direction, the plurality of pairs of electrodes including the electrodes 3 and 4 are not always necessary. That is, only at least a pair of electrodes may be provided.

For example, the electrode 3 is an electrode connected to the hot potential, and the electrode 4 is an electrode connected to the ground potential. However, the electrode 3 may be connected to the ground potential and the electrode 4 may be connected to the hot potential. In the acoustic wave device 1, as described above, at least a pair of electrodes are the electrode connected to the hot potential or the electrode connected to the ground potential, and a floating electrode is not provided.

FIG. 14 is a graph illustrating resonance characteristics of the acoustic wave device illustrated in FIG. 11. The design parameters of the acoustic wave device 1 having the resonance characteristics are as follows.
Piezoelectric layer 2: LiNbO₃ with Euler angles (0°, 0°, 90°)
Thickness: about 400 nm
Length of region where electrodes 3 and 4 overlap as seen in direction orthogonal to length direction of electrodes 3 and 4, that is, excitation region C: about 40 μm
Number of pairs of electrodes consisting of electrodes 3 and 4:21 pairs
Center-to-center distance between electrodes: about 3 μm
Width of electrodes 3 and 4: about 500 nm
d/p: about 0.133
Insulating layer 7: silicon oxide film with thickness of about 1 μm
Support 8: Si

The length of the excitation region C is a dimension of the excitation region C along the length direction of the electrodes 3 and 4.

In the acoustic wave device 1, the electrode-to-electrode distances of the electrode pairs including the electrodes 3 and 4 are all equal or substantially equal in the plurality of pairs. That is, the electrodes 3 and the electrodes 4 are arranged with equal or substantially equal pitches.

As is clear from FIG. 14, good resonance characteristics with the fractional band width of about 12.5% are obtained even though no reflector is provided.

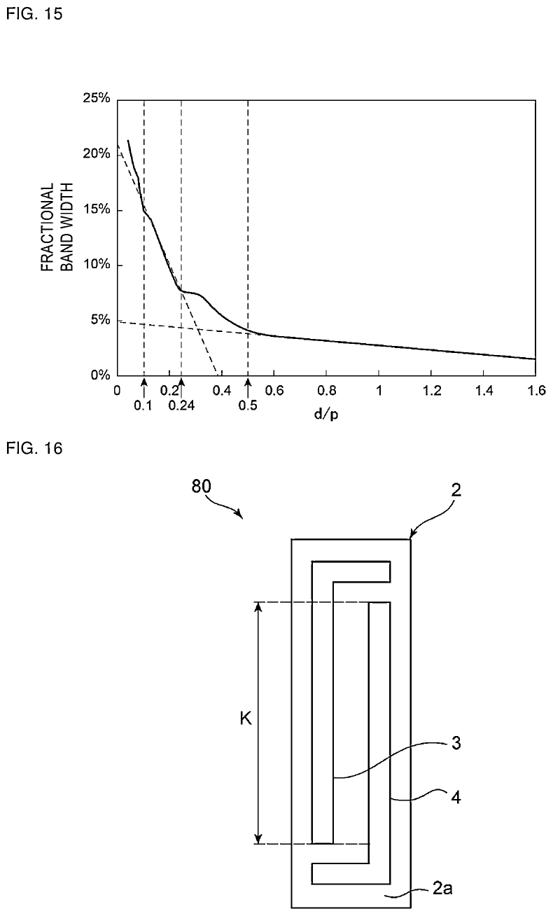

As described above, in the acoustic wave device 1, for example, d/p is less than or equal to about 0.5, and more preferably less than or equal to about 0.24, where d is the thickness of the piezoelectric layer 2 and p is the center-to-center distance between the electrode 3 and the electrode 4. This will be described with reference to FIG. 15.

A plurality of acoustic wave devices are obtained in the same or substantially the same manner as the acoustic wave device having the resonance characteristics illustrated in FIG. 14, except that d/p is changed. FIG. 15 is a graph illustrating a relationship between d/p and the fractional band width of the acoustic wave device as a resonator.

As is clear from FIG. 15, when d/p>0.5, the fractional band width is less than about 5% even if d/p is adjusted. On the other hand, when d/p≤about 0.5, the fractional band width can be set to more than or equal to about 5% by changing d/p within that range, that is, a resonator with a high coupling coefficient can be configured. Furthermore, when d/p is less than or equal to about 0.24, the fractional band width can be increased to more than or equal to about 78. In addition, by adjusting d/p within this range, a resonator with an even wider fractional band width can be obtained, and a resonator with an even higher coupling coefficient can be realized. Therefore, it can be seen that, by setting d/p to less than or equal to about 0.5, a resonator with a high coupling coefficient can be configured using the thickness-shear mode bulk wave.

FIG. 16 is a plan view of an acoustic wave device that uses a thickness-shear mode bulk wave. In an acoustic wave device 80, a pair of electrodes, including an electrode 3 and an electrode 4, are provided on a first main surface 2a of a piezoelectric layer 2. Note that K in FIG. 16 is an intersection width. As described above, in the acoustic wave device of the present invention, the number of pairs of electrodes may be one. Even in this case, for example, when the d/p is less than or equal to about 0.5, the thickness-shear mode bulk wave can be effectively excited.

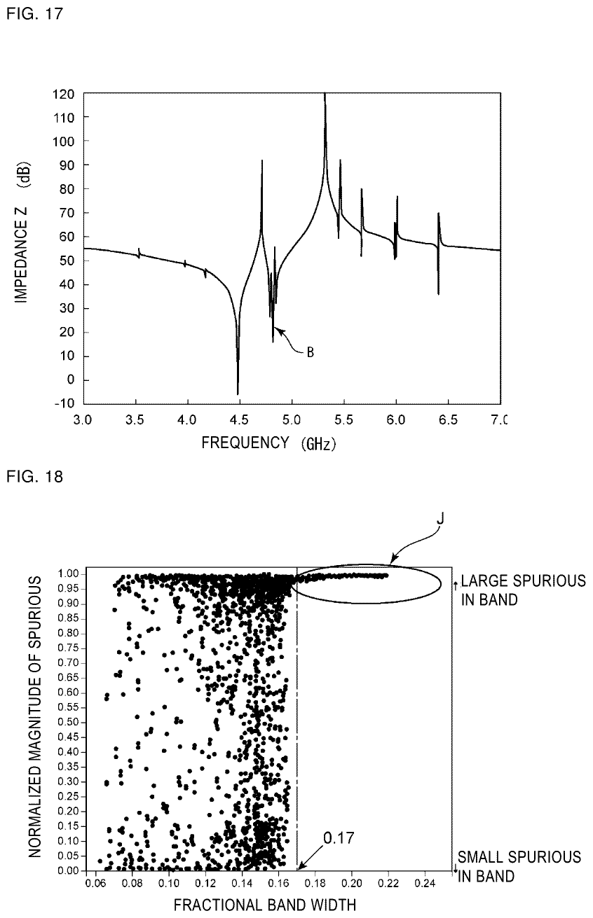

In the acoustic wave device 1, for example, it is preferable that a metallization ratio MR of any adjacent electrodes 3 and 4 of the plurality of electrodes 3 and 4 with respect to the excitation region C, which is a region where the adjacent electrodes 3 and 4 overlap when viewed in their facing direction, satisfies MR≤about 1.75 (d/p)+0.075. In that case, a spurious response can be effectively reduced. This will be described with reference to FIGS. 17 and 18. FIG. 17 is a reference diagram illustrating an example of the resonance characteristics of the acoustic wave device 1. A spurious response indicated by an arrow B appears between a resonant frequency and an anti-resonant frequency. d/p=about 0.08 and the Euler angles of LiNbO₃ are (0°, 0°, 90°). The metallization ratio MR is about 0.35.

The metallization ratio MR will be described with reference to FIG. 10B. In the electrode structure of FIG. 10B, when focusing on a pair of electrodes 3 and 4, it is assumed that only this pair of electrodes 3 and 4 is provided. In this case, a portion surrounded by a dashed-dotted line is the excitation region C. When the electrode 3 and the electrode 4 are viewed in the direction orthogonal or substantially orthogonal to the length direction of the electrodes 3 and 4, that is, in their facing direction, the excitation region C is a region of the electrode 3 that overlaps the electrode 4, a region of the electrode 4 that overlaps the electrode 3, and a region between the electrode 3 and the electrode 4 where the electrode 3 and the electrode 4 overlap each other. An area of the electrodes 3 and 4 in the excitation region C with respect to the area of the excitation region C is the metallization ratio MR. That is, the metallization ratio MR is the ratio of the area of the metallization portion to the area of the excitation region C.

When a plurality of pairs of electrodes are provided, the ratio of the metallization portion included in the entire or substantially entire excitation region to the total area of the excitation region may be MR.

FIG. 18 is a diagram illustrating a relationship between a fractional band width and a phase rotation amount of the spurious impedance normalized by about 180 degrees as the magnitude of the spurious response when a large number of acoustic wave resonators are configured according to the configuration of the acoustic wave device 1. The fractional band width is adjusted by changing the film thickness of the piezoelectric layer and the dimensions of the electrodes. FIG. 18 illustrates the results when a Z-cut LiNbO₃ piezoelectric layer is used, but the same or substantially the same tendency is obtained also when piezoelectric layers with other cut-angles are used.

In a region surrounded by an ellipse J in FIG. 18, the spurious response is as large as about 1.0. As is clear from FIG. 18, when the fractional band width exceeds about 0.17, that is, exceeds about 17%, a large spurious response with a spurious level of more than or equal to about 1 appears in a pass band even when the parameters defining the fractional band width are changed. That is, as in the resonance characteristics illustrated in FIG. 17, a large spurious response indicated by the arrow B appears within the band. Therefore, the fractional band width is, for example, preferably less than or equal to about 178. In this case, the spurious can be reduced by adjusting the film thickness of the piezoelectric layer 2, the dimensions of the electrodes 3 and 4, or the like.

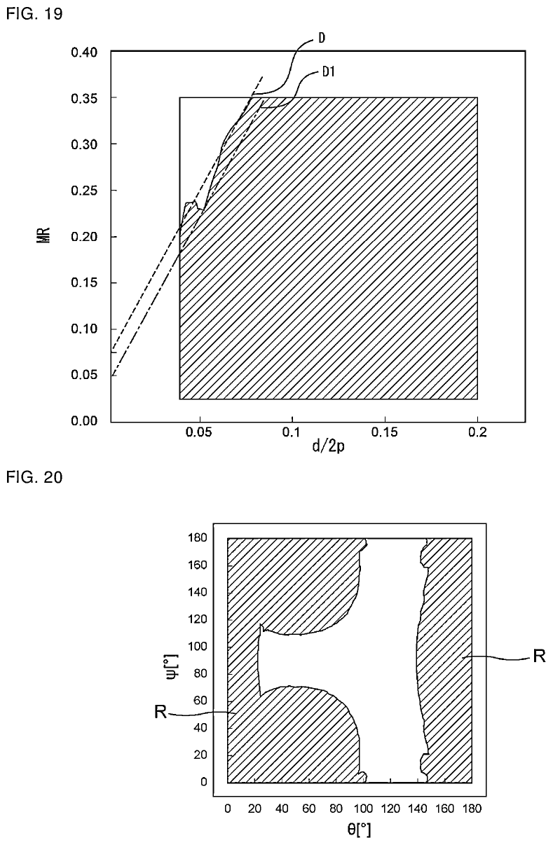

FIG. 19 is a diagram illustrating a relationship among d/2p, the metallization ratio MR, and the fractional band width. In the acoustic wave device, various acoustic wave devices having different values of d/2p and different values of MR are provided, and the fractional band width is measured. A hatched portion to the right of a dashed line D illustrated in FIG. 19 is a region where the fractional band width is less than or equal to about 17%. The boundary between the hatched region and the non-hatched region is represented by MR=about 3.5 (d/2p)+0.075. That is, MR=about 1.75 (d/p)+0.075. MR 5 about Therefore, for example, 1.75 (d/p)+0.075 is preferably satisfied. In this case, the fractional band width is easily set to less than or equal to about 17%. More preferably, for example, it is the region in FIG. 19 to the right of a dashed-dotted line D1 indicating MR=about 3.5 (d/2p)+0.05. That is, when MR≤about 1.75 (d/p)+0.05, the fractional band width can be reliably set to less than or equal to about 17%.

FIG. 20 is a diagram illustrating a map of the fractional band width with respect to the Euler angles (0°, θ, ψ) of LiNbO₃ when d/p is infinitely close to 0. A plurality of hatched regions R illustrated in FIG. 20 are regions where the fractional band width of more than or equal to about 2% is obtained. When φ in the Euler angles (φ, θ, ψ) is within the range of about 0°±5°, the relationship between θ and ψ and the fractional band width is the same or substantially the same as that illustrated in FIG. 20. Also when the piezoelectric layer is made of lithium tantalate (LiTaO₃), the relationship between θ and ψ in the Euler angles (within the range of 0°±5°, θ, ψ) and BW is the same or substantially the same as that illustrated in FIG. 20.

Therefore, when φ in the Euler angles (φ, θ, ψ) of the lithium niobate or lithium tantalate of the piezoelectric layer is within the range of about 0°±5° and θ and φ are within the range of any of the regions R illustrated in FIG. 20, the fractional band width can be sufficiently widened, which is preferable.

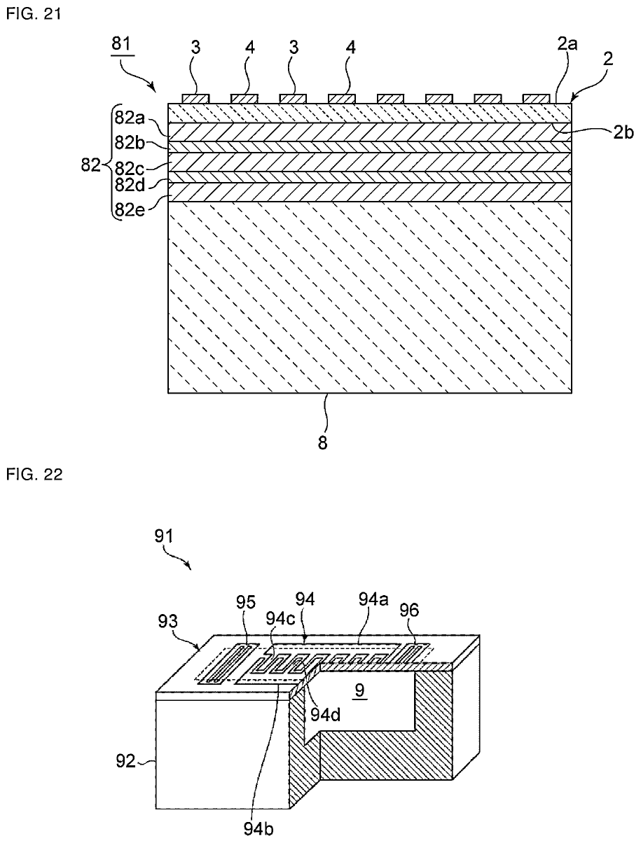

FIG. 21 is an elevational cross-sectional view of an acoustic wave device including an acoustic multilayer film.

In an acoustic wave device 81, an acoustic multilayer film 82 is laminated on a second main surface 2b of a piezoelectric layer 2. The acoustic multilayer film 82 has a multilayer structure including low acoustic impedance layers 82a, 82c, and 82e with a relatively low acoustic impedance and high acoustic impedance layers 82b and 82d with a relatively high acoustic impedance. Using the acoustic multilayer film 82 makes it possible to confine the thickness-shear mode bulk wave in the piezoelectric layer 2 without using the cavity 9 in the acoustic wave device 1. In the acoustic wave device 81, resonance characteristics based on the thickness-shear mode bulk wave can be obtained by setting the above d/p to, for example, less than or equal to about 0.5. In the acoustic multilayer film 82, the number of the low acoustic impedance layers 82a, 82c, and 82e and high acoustic impedance layers 82b and 82d laminated is not particularly limited. It is sufficient that at least one high acoustic impedance layer 82b or 82d is disposed farther from the piezoelectric layer 2 than the low acoustic impedance layers 82a, 82c, and 82e.

The low acoustic impedance layers 82a, 82c, and 82e and the high acoustic impedance layers 82b and 82d can be made of any appropriate material as long as the above acoustic impedance relationship is satisfied. Examples of the material of the low acoustic impedance layers 82a, 82c, and 82e include silicon oxide or silicon oxynitride, and the like. For example, alumina, silicon nitride, metal or the like can be used as the material of the high acoustic impedance layers 82b and 82d.

FIG. 22 is a partially cutaway perspective view for explaining an acoustic wave device that uses a Lamb wave.

An acoustic wave device 91 includes a support substrate 92. The support substrate 92 includes a recessed portion that is open on its upper surface. A piezoelectric layer 93 is laminated on the support substrate 92. A cavity 9 is thus provided. An IDT electrode 94 is provided on the piezoelectric layer 93 above the cavity 9. On both sides of the IDT electrode 94 in the acoustic wave propagation direction, reflectors 95 and 96 are provided. In FIG. 22, an outer periphery of the cavity 9 is indicated by a dashed line. Here, the IDT electrode 94 includes first and second busbars 94a and 94b, a plurality of first electrode fingers 94c, and a plurality of second electrode fingers 94d. The plurality of first electrode fingers 94c are connected to the first busbar 94a. The plurality of second electrode fingers 94d are connected to the second busbar 94b. The plurality of first electrode fingers 94c and the plurality of second electrode fingers 94d are interdigitated with each other.

In the acoustic wave device 91, an AC electric field is applied to the IDT electrode 94 on the cavity 9 to excite a Lamb wave as a plate wave. Since the reflectors 95 and 96 are provided on both sides, resonance characteristics due to the Lamb wave can be obtained.

As described above, acoustic wave devices according to example embodiments of the present invention may use the plate wave. In the example illustrated in FIG. 22, the IDT electrode 94, the reflector 95, and the reflector 96 are provided on the main surface corresponding to the first main surface 14a of the piezoelectric layer 14 illustrated in FIG. 1 and the like. On the other hand, in an acoustic wave device according to an example embodiment of the present invention, a pair of comb-shaped electrodes and a plurality of third electrode fingers are provided on the first main surface 14a. When the acoustic wave device uses the plate wave, a pair of comb-shaped electrodes and a plurality of third electrode fingers, as well as the reflector 95 and the reflector 96 may be provided on the first main surface 14a of the piezoelectric layer 14 in the first to fourth example embodiments. In this case, the pair of comb-shaped electrodes and the plurality of third electrode fingers may be sandwiched between the reflectors 95 and 96 in the electrode finger orthogonal direction.

In the acoustic wave devices of the first to fourth example embodiments, for example, the acoustic multilayer film 82 illustrated in FIG. 21 may be provided as an acoustic reflection film between the support and the piezoelectric layer. Specifically, the support and the piezoelectric layer may be arranged such that at least a portion of the support and at least a portion of the piezoelectric layer face each other across the acoustic multilayer film 82. In this case, it is sufficient that low acoustic impedance layers and high acoustic impedance layers are alternately laminated in the acoustic multilayer film 82. The acoustic multilayer film 82 may be an acoustic reflection portion in the acoustic wave device.

In the acoustic wave devices according to the first to fourth example embodiments that use the thickness-shear mode bulk wave, as described above, d/p is, for example, preferably less than or equal to about 0.5, and more preferably less than or equal to about 0.24. This makes it possible to obtain even better resonance characteristics.

Furthermore, in the excitation region of the acoustic wave devices according to the first to fourth example embodiments that use the thickness-shear mode bulk wave, as described above, for example, MR<about 1.75 (d/p)±0.075 is preferably satisfied. More specifically, MR≤about 1.75 (d/p)±0.075 is preferably satisfied, where MR is the metallization ratio of the first and third electrode fingers and the second and third electrode fingers to the excitation region. In this case, a spurious response can be more reliably reduced or prevented.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer;
a first comb-shaped electrode on the piezoelectric layer, including a first busbar and a plurality of first electrode fingers each including one end connected to the first busbar, and being connected to an input potential;
a second comb-shaped electrode on the piezoelectric layer, including a second busbar and a plurality of second electrode fingers each including one end connected to the second busbar and being interdigitated with the plurality of first electrode fingers, and being connected to an output potential; and
a reference potential electrode including a plurality of third electrode fingers on the piezoelectric layer and aligned with the first electrode fingers and the second electrode fingers in a direction in which the first electrode fingers and the second electrode fingers are arranged, and a plurality of connection electrodes connecting adjacent third electrode fingers, the reference potential electrode being at least partially provided between the first comb-shaped electrode and the second comb-shaped electrode and connected to a reference potential; wherein
an order in which a first electrode finger, a second electrode finger, and a third electrode finger are arranged is such that, starting from the first electrode finger, the first electrode finger, the third electrode finger, the second electrode finger, and the third electrode finger define one period; and
the reference potential electrode includes at least three potential connection portions connected to the reference potential.

2. The acoustic wave device according to claim 1, wherein, when a direction orthogonal or substantially orthogonal to a direction in which the first electrode finger, the second electrode finger, and the third electrode finger extend is an electrode finger orthogonal direction, the plurality of potential connection portions of the reference potential electrode are located at two third electrode fingers at both ends in the electrode finger orthogonal direction, among the plurality of third electrode fingers, and in a portion between the two third electrode fingers.

3. The acoustic wave device according to claim 1, wherein all of the adjacent third electrode fingers in the reference potential electrode are connected to each other by the connection electrodes.

4. The acoustic wave device according to claim 1, wherein
some of the third electrode fingers among all of the adjacent third electrode fingers in the reference potential electrode are not connected to each other by the connection electrode, and the reference potential electrode includes a plurality of electrode portions that are not connected to each other by the connection electrode; and
each of the electrode portions includes the potential connection portion.

5. The acoustic wave device according to claim 1, further comprising:
a connection wiring on the piezoelectric layer and connected to the potential connection portion of the reference potential electrode; wherein
the potential connection portion is connected to the reference potential through the connection wiring;
at least one of the first busbar and the second busbar is divided to include a plurality of split busbar portions; and
the connection wiring passes between the split busbar portions.

6. The acoustic wave device according to claim 1, wherein the acoustic wave device is structured to excite a plate wave.

7. The acoustic wave device according to claim 1, wherein the acoustic wave device is structured to excite a thickness-shear mode bulk wave.

8. The acoustic wave device according to claim 1, further comprising:
a support laminated on the piezoelectric layer; wherein
an acoustic reflection portion is provided at a position on the support that overlaps with the plurality of first electrode fingers, the plurality of second electrode fingers, and the plurality of third electrode fingers in plan view along a lamination direction of the support and the piezoelectric layer; and
d/p is less than or equal to about 0.5, where p is the longest distance of a center-to-center distance between adjacent first and third electrode fingers and a center-to-center distance between adjacent second and third electrode fingers, and d is a thickness of the piezoelectric layer.

9. The acoustic wave device according to claim 8, wherein d/p is less than or equal to about 0.24.

10. The acoustic wave device according to claim 8, wherein
the acoustic reflection portion includes a cavity; and
a portion of the support and a portion of the piezoelectric layer face each other across the cavity.

11. The acoustic wave device according to claim 8, wherein
the acoustic reflection portion includes an acoustic reflection film including a high acoustic impedance layer with a relatively high acoustic impedance and a low acoustic impedance layer with a relatively low acoustic impedance; and
at least a portion of the support and at least a portion of the piezoelectric layer face each other across the acoustic reflection film.

12. The acoustic wave device according to claim 8, wherein
an excitation region is a region where the first electrode finger and the third electrode finger adjacent to each other overlap each other in an electrode finger orthogonal direction, which is a direction orthogonal or substantially orthogonal to a direction in which the first electrode finger, the second electrode finger, and the third electrode finger extend, and a region between the centers of the adjacent first and third electrode fingers, and a region where the adjacent second and third electrode finger in the electrode finger orthogonal direction and a region between the centers of the adjacent second and third electrode finger; and
MR≤about 1.75 (d/p)+0.075 is satisfied, where MR is a metallization ratio of the first electrode finger and the third electrode finger, and the second electrode finger and the third electrode finger to the excitation region.

13. The acoustic wave device according to claim 1, wherein the piezoelectric layer includes lithium tantalate or lithium niobate.

14. The acoustic wave device according to claim 13, wherein
Euler angles (φ, θ, ψ) of the lithium niobate or lithium tantalate of the piezoelectric layer are within the range of the following Expression (1), Expression (2), or Expression (3):
(within the range of 0°±10°, 0° to 25°, any ψ) Expression (1);
(within the range of 0°±10°, 25° to 100°, 0° to 75° [(1−(θ−50)²/2500)]^{1/2} or 180°−75°[(1−(θ−50)²/2500)]^{1/2} to 180°) Expression (2); or
(within the range of 0°±10°, 180°−40° [(1−(ψ−90)²/8100)]^{1/2} to 180°, any ψ) Expression (3).

15. The acoustic wave device according to claim 1, further comprising a support on which the piezoelectric layer is provided.

16. The acoustic wave device according to claim 15, wherein
the support includes a support substrate and an insulating layer on the support substrate; and
the piezoelectric layer is provided on the insulating layer.

17. The acoustic wave device according to claim 16, wherein the support substrate includes silicon or aluminum oxide.

18. The acoustic wave device according to claim 16, wherein the insulating layer includes silicon oxide or tantalum oxide.

19. The acoustic wave device according to claim 1, wherein the piezoelectric layer includes LiNbO₃ or LiTaO₃.

20. The acoustic wave device according to claim 16, wherein the insulating layer includes a recess portion.
